(19) United States
(12) Patent Application Publication
(10) Pub. No.: US 2017/0129700 A1
(43) Pub. Date: May 11, 2017

(54) OVERFLOW BLOCKING APPARATUS FOR TANK LORRY

(71) Applicant: Young Soo CHOI, Gyeongsangbuk-do (KR)

(72) Inventor: Young Soo CHOI, Gyeongsangbuk-do (KR)

(21) Appl. No.: 15/322,314

(22) PCT Filed: Jul. 2, 2015
(86) PCT No.: PCT/KR2015/006841

§ 371 Date: Dec. 27, 2016

(30) Foreign Application Priority Data
Jul. 2, 2014 (KR) 10-2014-0082398

(51) Int. Cl. B65D 90/26; G01R 31/02; F16K 17/00; G01F 23/64

(52) U.S. Cl. CPC B65D 90/26; G01F 23/64; G01R 31/025; F16K 17/00

(57) ABSTRACT

An overflow blocking apparatus for a tank lorry comprises: a main body (10) having a first cylinder (11) and a second cylinder (12) formed therein, a first air supply passage (13) connected to a side of the first cylinder, and a first air discharge passage (15) formed at one side; a piston (20) having one end connected to a rod (21) and the other end elastically supported with a spring (22); a lower main body (30) connected to the main body and having a lot hole (31) therein and a second air supply passage (32) and a second air discharge passage (33) connected to the wall of the lot hole; a lot (40) capable of reciprocating in the lot hole; a tube (50) provided in the form of wrapping the outer side of the lower main body; and a float (60) provided to be lifted by buoyancy of oil.

### BACKGROUND

The present invention relates to an improvement of the overflow blocking apparatus for a tank lorry as disclosed in Korean Patent Application Laid-open No.2013-0068649 (filed on Jun. 14, 2013), and more particularly, to an overflow blocking apparatus for a tank lorry that is mounted on the upper portion of a storage tank of the tank lorry and discharges oil steam from the interior of the storage tank upon the injection of oil thereinto to prevent an internal pressure of the storage tank from being excessively raised, while blocking a ground wire of a place of delivery when an amount of oil injected is over an upper limit for oil injection to allow a pump located at the place of delivery to temporarily stop.

Generally, a tank lorry carrying oil or chemicals is configured wherein openings are formed on the internal space of a storage tank in such a manner as to have limit points for maximum load capacities indicated at the inside thereof and oil supply valves are disposed on mounting holes formed on the bottom surface of the internal space of the storage tank.

Accordingly, oil is supplied or discharged to and from an oil supply pipe under the storage tank of the tank lorry, and then, the oil supply valves are open and closed by means of power generating means disposed on the tank lorry according to the operation of a control valve disposed on top of the storage tank.

In case of the general tank lorry as mentioned above, however, a driver has to move to the top of the tank lorry to open the covers of the openings when the oil or chemicals is (are) loaded to the tank lorry, irrespective of whether a metering instrument is provided on a supply facility (not shown in the drawing) supplying the loaded material, has to check that the loaded material is filled to gauge bars formed on the openings by his or her naked eyes, and finally has to manipulate the control switch and a venting valve. Under the above-mentioned loading process, however, it is inconvenient for the driver to perform the loading operations, and if a flammable material like oil is loaded, there are dangers of explosion and fire. Further, if toxic chemicals are loaded, vaporized chemicals are emitted to the air to cause environmental pollution and to make a worker exposed to the toxic material. On the other hand, the gauge bar just indicates a maximum loading capacity, so that when a small amount of oil or the like is loaded, the amount of oil loaded cannot be accurately checked.

So as to solve the above-mentioned problems occurring in the general tank lorry, Korean Utility Model Registration No. 365399 (prior art 1) and No.378860 (prior art 2) are disclosed to suggest a configuration of a gauge for a tank lorry, and even in case of the two prior arts, however, a driver has to move to the top of the tank lorry, check the loaded amount, and manipulate the control switch, in an inconvenient way.

As shown in FIGS. 1 and 2, accordingly, the inventor has suggested an overflow blocking apparatus A2 for a tank lorry, which is disclosed in Korean Patent Application Laid-open No.2013-0068649 (filed on Jun. 14, 2013) (prior art 3). The conventional overflow blocking apparatus A2 includes: an overflow blocking valve A2-1 including a body 100 attached to a top plate T-1 of a storage tank T, an air supply hole L1 formed on one side thereof, an air discharge hole L2 formed on the other side thereof, an operating hole 110 formed on the center thereof in such a manner as to be coupled to a lot 400, an air supply passage 120 connecting the air supply hole L1 and the operating hole 110, and an air discharge passage 130 connected to the air discharge hole L2, a tube body 200 coupled to the lower portion of the body 100 in such a manner as to be disposed vertically in the interior of the storage tank T and having a hollow portion formed at the inside thereof, a lower body 300 inserted into the tube body 200 in such a manner as to be coupled to the lower end periphery of the body 100 and having a third air supply passage 390 formed at the inside thereof in such a manner as to communicate with the air supply passage 120, a lot hole 310 formed at the center thereof in such a manner as to fit the lot 400 thereto, and a steel plate 320 attached to the underside thereof, the lot 400 fitted to the lot hole 310 of the lower body 300 in such a manner as to be fittedly coupled to the operating hole 110 of the body 100 and operated ascendably and descendably in contact with a float 500, the float 500 inserted into the tube body 200 in such a manner as to be moved up by means of the buoyancy of oil, and a locking device 600 coupled to the upper portion of the body 100 to suppress the upward movement of the lot 400 so that the upward movement of the float 500 is blocked while the tank lorry is being driven in the state where the storage tank T is empty; and an overflow sensor A2-2 connected to the air discharge hole L2 of the body 100 of the overflow blocking sensor A2-1 to stop an oil supply pump P located on a place of delivery if oil exceeding a dangerous level is supplied to the storage tank T.

In case of the prior art 3, however, the body 100 having the air supply hole L1 and the air discharge hole L2 formed thereon is disposed separately from the locking device 600 blocking the upward movement of the float 500. Further, an air supply inlet of the body 100 is formed separately from an air supply inlet of the locking device 600. As a result, the conventional overflow blocking apparatus is complicated in configuration and causes a high manufacturing cost.

### PRIOR ART DOCUMENTS

[Prior art 1] Korean Utility Model Registration No. 365399 (issued on Oct. 22, 2004)

[Prior art 2] Korean Utility Model Registration No. 378860 (issued on Mar. 16, 2005)

[Prior art 3] Korean Patent Application Laid-open No.2013-0068649 (filed on Jun. 14, 2013)

### SUMMARY OF THE INVENTION

Accordingly, the present invention has been made in view of the above-mentioned problems occurring in the prior art, and it is an object of the present invention to provide an overflow blocking apparatus for a tank lorry that is capable of automatically blocking an inlet valve when oil exceeding an upper limit for oil injection is injected, while being simple in a configuration, easy in manufacturing, and improving reliability in opening/closing operations.

### Technical Solution

To accomplish the above-mentioned object, according to the present invention, there is provided an overflow blocking apparatus for a tank lorry including overflow sensors disposed on top of a storage tank to sense whether oil overflows, wherein each overflow sensor includes: a body having a first cylinder and a second cylinder communicating with one side end portion of the first cylinder disposed at the inside thereof, a first air supply passage connected to the side periphery of the first cylinder to introduce air thereinto, and a first air discharge passage formed on one side thereof; a piston reciprocated in the first cylinder in such a manner as to be connected to a rod reciprocating in the second cylinder at one side end thereof and supported elastically against a spring at the other side end thereof; a lower body connected to the end of the second cylinder of the body and having a lot hole formed at the center of the interior thereof and a second air supply passage and a second air discharge passage connected to the wall surface of the lot hole, the second air supply passage communicating with the first air supply passage and the second air discharge passage communicating with the first air discharge passage; a lot reciprocated in the state where the outer peripheral surface thereof comes into contact with the inner peripheral surface of the lot hole and having a depressed groove formed on one side of the outer peripheral surface thereof so that a space is formed between the outer and inner peripheral surfaces of the lot hole; a tube body adapted to surround the outer periphery of the lower body, while having an internal space at the inside thereof; and a float moved up in the internal space of the tube body by means of the buoyancy of oil.

### Advantageous Effects

According to the present invention, the overflow blocking apparatus for a tank lorry is capable of automatically blocking an inlet valve when oil exceeding an upper limit for oil injection is injected into the tank lorry, while being simple in a configuration, easy in manufacturing, and improving reliability in opening/closing operations, thereby optimizing safety in use and economical benefits.

### BRIEF DESCRIPTION OF DRAWINGS

FIG. 1 is a side view showing a conventional overflow blocking apparatus (as disclosed in Prior art 3) for a tank lorry.

FIG. 2 is a sectional view showing the conventional overflow blocking apparatus (as disclosed in Prior art 3) for a tank lorry.

FIG. 3 is a side view showing an overflow blocking apparatus for a tank lorry according to the present invention.

FIG. 4 is an enlarged view showing a portion around an overflow sensor of FIG. 3.

FIG. 5 is a sectional view showing an overflow sensor adopted in the present invention.

FIGS. 6 and 7 are sectional views showing the sequential operations of the overflow sensor according to the present invention.

FIGS. 8 and 9 are enlarged sectional views showing the sequential operations of a ground sensor of FIG. 3.

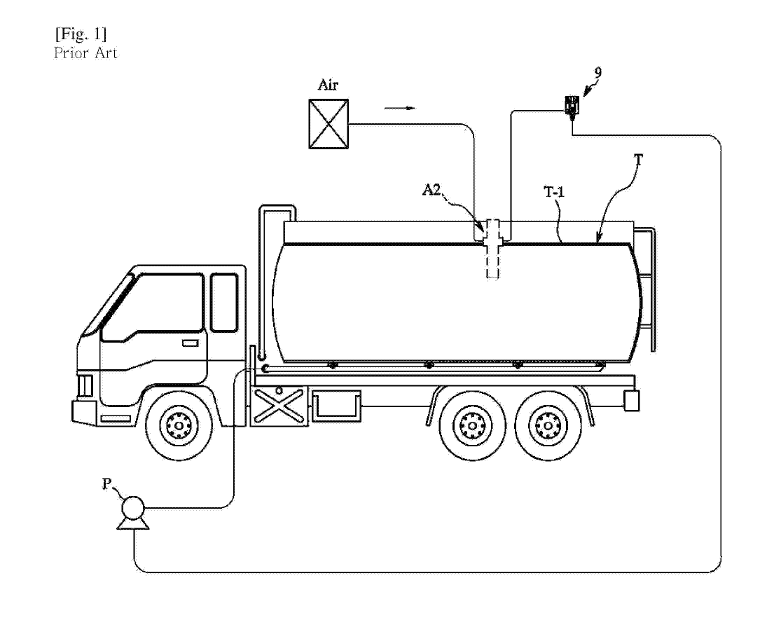

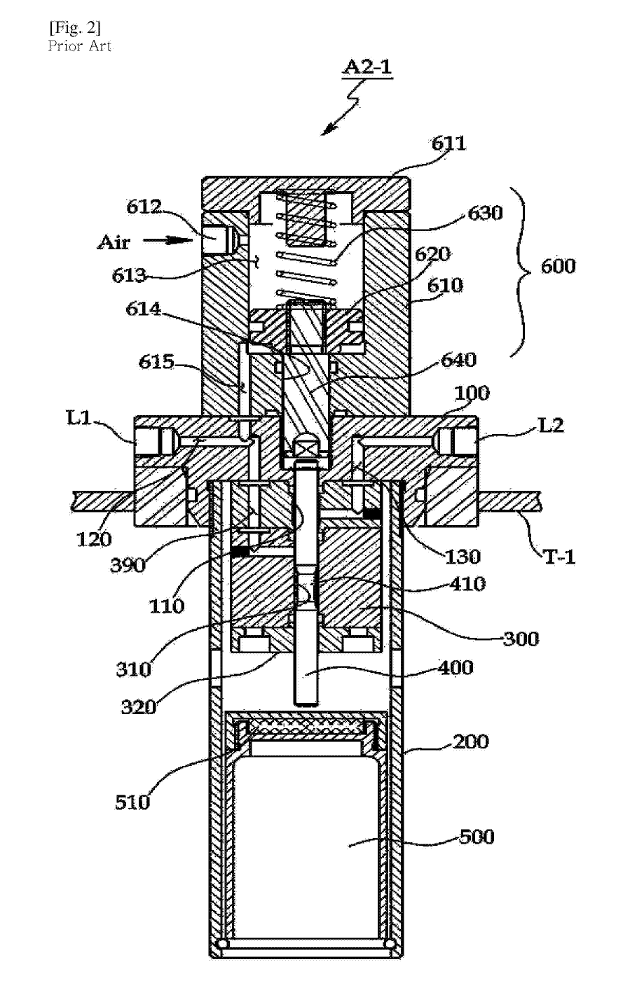

### BEST MODE FOR INVENTION

Hereinafter, an explanation on a preferred embodiment of the present invention will be in detail given with reference to the attached drawings. Before the present invention is disclosed and described, it is to be understood that the disclosed embodiments are merely exemplary of the invention, which can be embodied in various forms. In the description, if it is determined that the detailed explanation on the well known technology related to the present invention makes the scope of the present invention not clear, the explanation will be avoided for the brevity of the description.

### DETAILED DESCRIPTION OF THE INVENTION

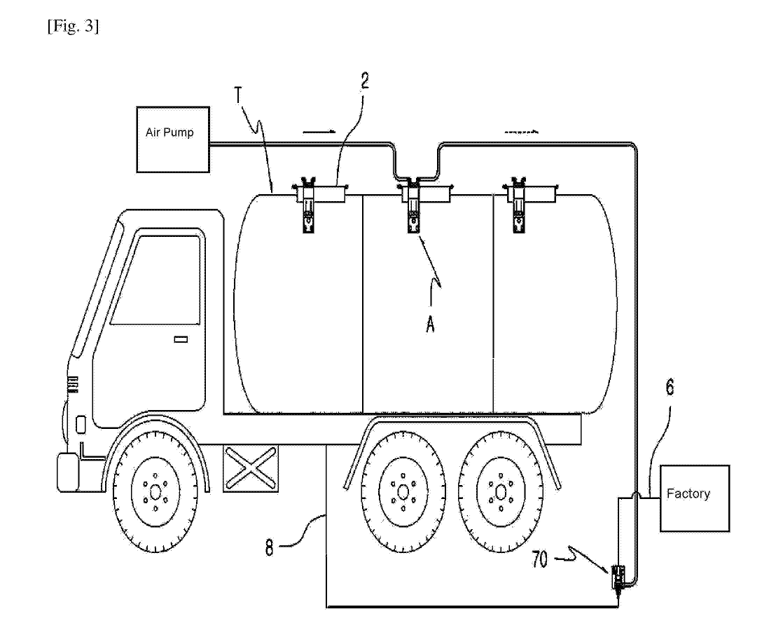

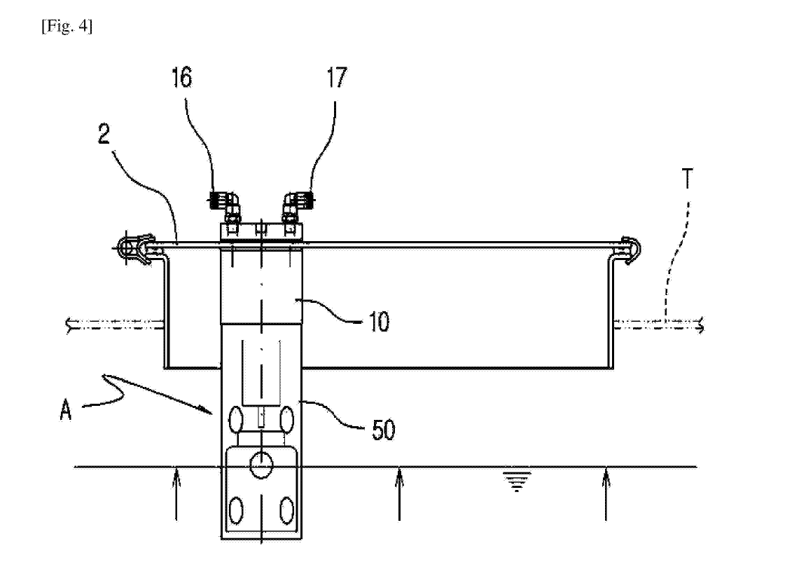

FIG. 3 is a side view showing an overflow blocking apparatus for a tank lorry according to the present invention, and FIG. 4 is an enlarged view showing a portion around an overflow sensor of FIG. 3.

Referring to FIGS. 3 and 4, an overflow blocking apparatus for a tank lorry according to the present invention is provided with overflow sensors A that are mechanical sensors for sensing a level of oil injected into a storage tank T to prevent the oil from being supplied over an upper limit, and the overflow sensors A are disposed on top of the storage tank T, more specifically, on main covers 2 located on the top of the storage tank T.

At this time, an air supply port 16 and an air discharge port 17, which supplies and discharges air to and from each overflow sensor A, are connected to the top of each overflow sensor A so that they are located above each main cover 2.

The air discharge inlets 17 are connected auxiliary to a ground sensor 70, and the ground sensor 70 is operated by the air supplied from the overflow sensors A to control whether the oil is supplied or not to a factory.

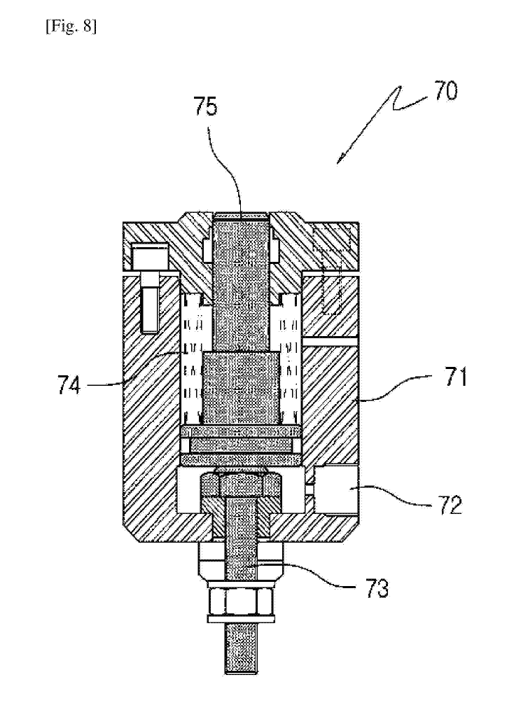

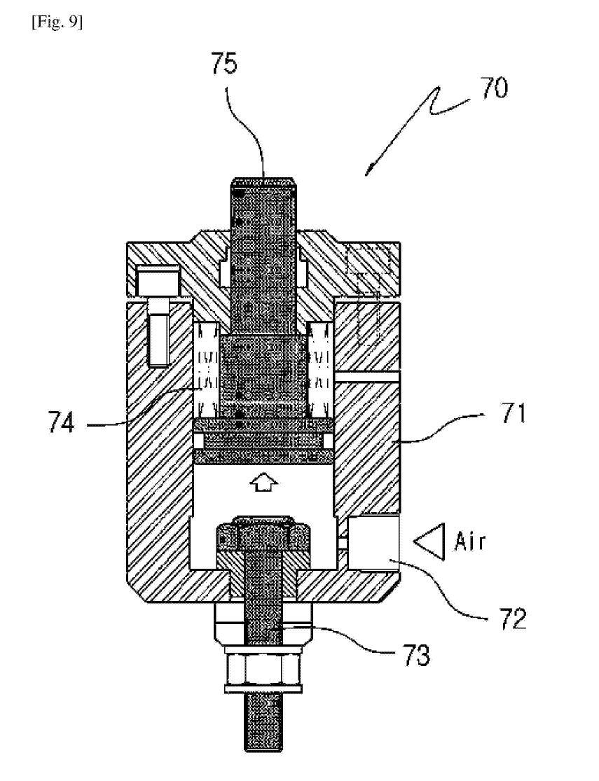

So as to connect the air discharge inlets 17 to the ground sensor 70, the ground sensor 70 is connected to an air line receiving the air from the air discharge inlets 17, while being connected to a factory ground wire 6 of the factory at one side thereof and connected to a vehicle ground wire 8 at the other side thereof. An explanation on the ground sensor 70 will be in detail given later with reference to FIGS. 8 and 9.

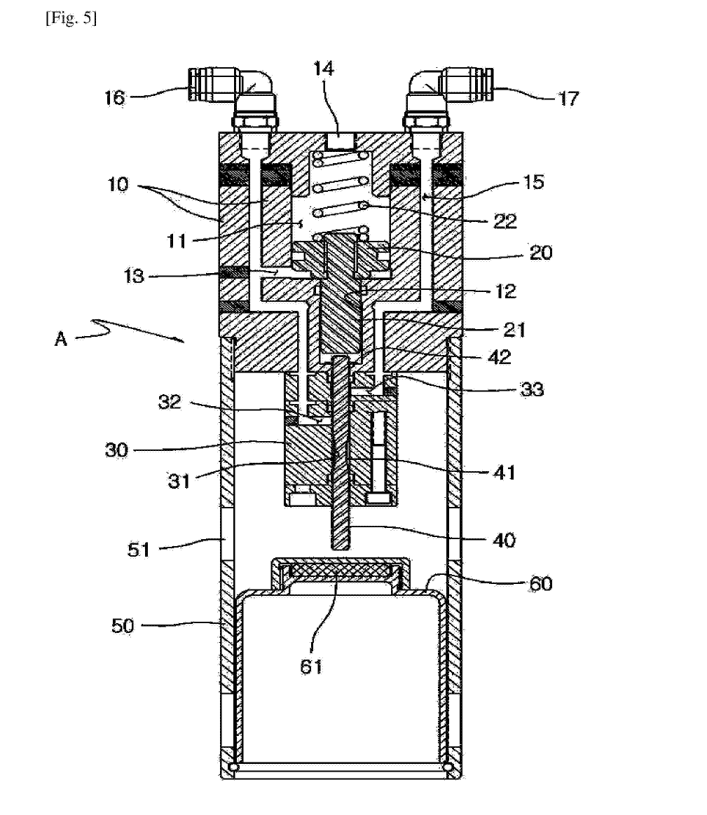

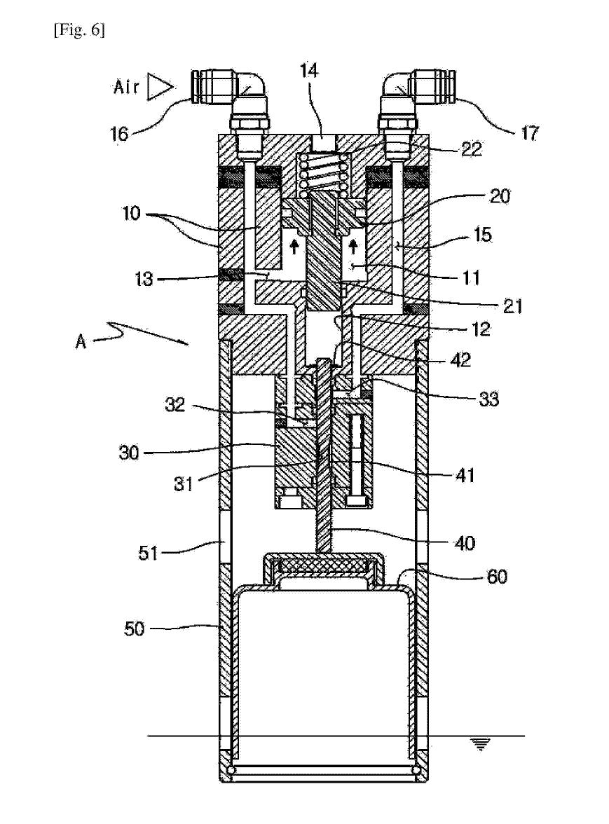

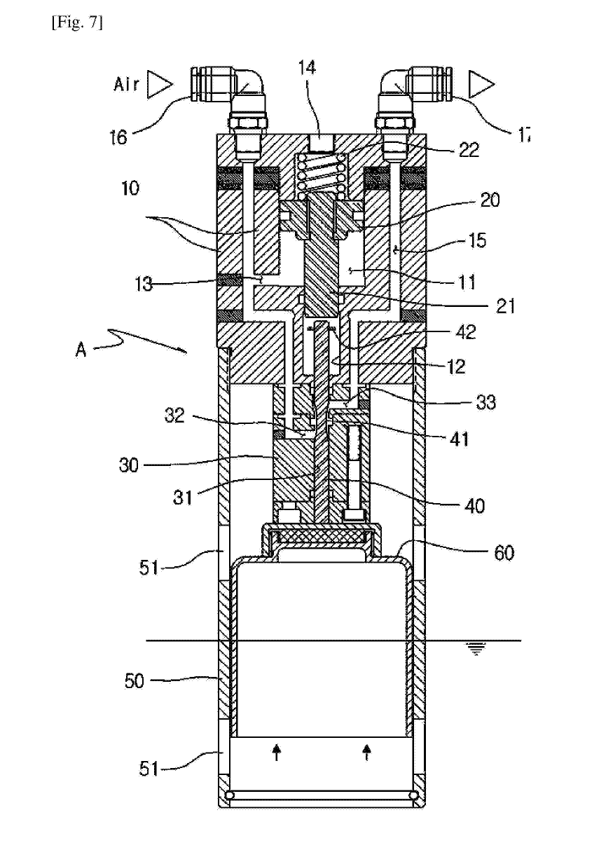

FIG. 5 is a sectional view showing the overflow sensor adopted in the present invention, and FIGS. 6 and 7 are sectional views showing the sequential operations of the overflow sensor according to the present invention.

As shown in FIG. 5, each overflow sensor A according to the present invention largely includes a body 10, a piston 20 reciprocated in the body 10, a lower body 30 connected to the body 10, a lot 40 reciprocated in the lower body 30, a tube body 50, and a float 60 reciprocated in the tube body 50.

The body 10 has a first cylinder 11 and a second cylinder 12 disposed at the inside thereof, and at this time, the second cylinder 12 communicates with one side end portion of the first cylinder 11 in such a manner as to be located linearly with respect to the first cylinder 11. Further, the body 10 has a first air supply passage 13 connected to the side periphery of the first cylinder 11 to introduce air thereinto and a first air discharge passage 15 formed on one side thereof.

In more detail, the piston 20 and the rod 21 are reciprocated correspondingly in the first cylinder 11 and the second cylinder 12, and so as to allow the reciprocating directions of the piston 20 and the rod 21 to become upward and downward directions of the storage tank T, the body 10 is vertically located. At this time, the first air supply passage 13 is connected to the air supply inlet 16 provided on the top of the body 10, and the first air discharge passage 15 is connected to the air discharge port 17 provided on the top of the body 10.

Further, the inner diameter of the second cylinder 12 is smaller than that of the first cylinder 11, and the inlet of the first air supply passage 13 for injecting the air into the first cylinder 11 is formed on the lower end portion of the first cylinder 11, so that the piston 20 can be moved up upon the injection of air.

The piston 20 is reciprocated in the state where the outer peripheral surface thereof comes into contact with the inner peripheral surface of the first cylinder 11. One side end of the piston 20 is connected to the rod 21 reciprocated in the second cylinder 12 and the other side end thereof is supported elastically against a coil type spring 22 so that when the piston 20 is moved up, the spring 22 becomes compressed to produce a repulsive force.

At this time, a venting hole 14 is formed on one side of a space in which the spring 22 is mounted in the first cylinder 11 in such a manner as to communicate with the outside, thereby preventing the air in the space where the spring 22 is mounted from being compressed when the piston 20 is moved up.

The lower body 30 is fixedly connected to the end of the body 10 in a direction where the second cylinder 12 is disposed and includes a lot hole 31 formed at the center of the interior thereof and a second air supply passage 32 and a second air discharge passage 33 connected to the wall surface of the lot hole 31, the second air supply passage 32 communicating with the first air supply passage 14 and the second air discharge passage 33 communicating with the first air discharge passage 15.

The lot 40 is reciprocated in the state where the outer peripheral surface thereof comes into contact with the inner peripheral surface of the lot hole 31, and at this time, the lot 40 has an inwardly depressed groove 41 formed on one side of the outer peripheral surface thereof so that a space is formed between the outer and inner peripheral surfaces of the lot hole 31 at only the portion where the depressed groove 41 is formed.

Accordingly, the second air supply passage 32 and the second air discharge passage 33 of the lower body 30 communicate with each other through the depressed groove 41 of the lot 40, and they will be in detail explained later when the operation of the present invention is described.

On the other hand, one side end of the lot 40 protrudes toward the internal space of the second cylinder 12 and the other side end thereof protrudes toward the internal space of the tube body 50. At this time, an outwardly protruding flange 42 is disposed on the protruding portion of the lot 40 toward the second cylinder 12 to prevent the lot 40 from being escaped from the lower body 30.

The tube body 50 is provided to surround the outer periphery of the lower body 30, while having an internal space at the inside thereof, and as shown, the tube body 50 is extended downwardly from the lower end periphery of the body 10.

In this case, the tube body 50 has at least one or more holes 51 formed thereon in such a manner as to connect the internal space thereof with an outside space, and thus, air as well as oil filled to the storage tank T is passed through the holes 51.

The float 60 is moved up in the internal space of the tube body 50 by means of the buoyancy of oil, and at this time, the float 60 has a magnet 51 disposed on top thereof. At least a portion of the lower body 30 is made of a metal material attachable to the magnet 51, so that if the float 60 is moved up, the top of the float 60 at a given position can be attached to the underside of the lower body 30.

Now, an operation of the overflow sensor A according to the present invention will be explained.

If oil is injected into the storage tank T and at the same time air is injected into the air supply port 16, in a stop state as shown in FIG. 5, the air passing through the first air supply passage 13 is injected into the lower end of the first cylinder 11 to move the piston 20 up, and the air introduced into the second air supply passage 32 becomes in a standby state by means of the inhibition of the lot 40, as shown in FIG. 6.

If the oil is continuously injected in this state, the surface of oil comes into contact with the float 60, and accordingly, the float 60 becomes gradually moved up by means of the buoyancy of the oil, so that the top of the float 60 is brought into contact with the underside of the lower body 30 and at this time the lot 40 is accordingly moved up.

Of course, if the float 60 reaches a maximum position in the tube body 50, the magnet 61 and the lower body 30 are attached to each other by means of their magnetic force, and unless they are artificially separated from each other, accordingly, the float 60 is not moved down.

When the lot 40 is moved up, the depressed groove 41 is connected to the second air supply passage 32 and the second air discharge passage 33 of the lower body 30, and accordingly, the air, which is in the standby state on the second air supply passage 32, is moved to the second air discharge passage 33 through the space formed by the depressed groove 41 and then to the first air discharge passage 15. Finally, the air is discharged to the air discharge port 17, and the air discharging is sensed by a separate device, thereby blocking the injection of the oil.

FIGS. 8 and 9 are enlarged sectional views showing the sequential operations of a ground sensor of FIG. 3.

If the ground wire is short-circuited by the air discharged from the air discharge port 17 upon the overflow sensing from the overflow sensor A, as shown in FIGS. 8 and 9, the ground sensor 70 checks whether a ground check system disposed on a place of delivery is short-circuited on the ground wire and stops an oil supply pump if short-circuited, thereby blocking the supply of the oil injected into the storage tank T.

In this case, the ground sensor 70 includes a cylinder housing 71 having an ascending/descending space formed at the interior thereof and an inlet 72 formed on one side thereof to introduce the air supplied from the overflow sensor A into the ascending/descending space, a first ground member 73 disposed on the lower portion of the cylinder housing 71, a second ground member 75 disposed ascendably and descendably in the ascending/descending space in such a manner as to be brought into contact with the first ground member 73 when moved down and to be separated from the first ground member 73 when moved up, and an elastic body 74 for moving the second ground member 75 to the first ground member 73 when the air is not introduced from the inlet 72.

In this case, the second ground member 75 may have a function like a piston, and the elastic body 74 may be a coil spring.

If the air is introduced into the ascending/descending space through the inlet 72, accordingly, the second ground member 75 is moved up by means of the pressure of air and is then separated from the first ground member 73 to block the electrical flow between the first ground member 73 and the second ground member 75, so that the operation of the pump for injecting the oil into the storage tank T stops to block the supply of oil.

As described above, the overflow blocking apparatus according to the present invention can automatically block the supply of oil at a given level when the oil is injected into the storage tank T of the tank lorry, while being simple in a configuration, having no danger of malfunctions, and being easy in manufacturing.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

<Explanations on Reference Numerals in the Drawing>

| | |
|---|---|
| 10: body | 11: first cylinder |
| 12: second cylinder | |
| 13: first air supply passage | |
| 14: venting hole | 15: first air discharge passage |
| 16: air supply port | 17: air discharge port |
| 20: piston | 21: rod |
| 22: spring | |
| 30: lower body | 31: lot hole |
| 32: second air discharge passage | |
| 33: second air discharge passage | |
| 40: lot | 41: depressed groove |
| 50: tube body | 51: hole |
| 60: float | 61: magnet |
| 70: ground sensor | 71: cylinder housing |
| 72: inlet | 73: first ground member |
| 74: elastic body | 75: second ground member |

1. An overflow blocking apparatus for a tank lorry, comprising:
overflow sensors (A) disposed on top of a storage tank (T) to sense whether oil overflows, wherein each overflow sensor (A) comprises:
a body (10) having a first cylinder (11) and a second cylinder (12) communicating with one side end portion of the first cylinder (11) disposed at the inside thereof, a first air supply passage (13) connected to the side periphery of the first cylinder (11) to introduce air thereinto, and a first air discharge passage (15) formed on one side thereof;
a piston (20) reciprocated in the first cylinder (11) in such a manner as to be connected to a rod (21) reciprocating in the second cylinder (12) at one side end thereof and supported elastically against a spring (22) at the other side end thereof;
a lower body (30) connected to the end of the second cylinder (12) of the body (10) and having a lot hole (31) formed at the center of the interior thereof and a second air supply passage (32) and a second air discharge passage (33) connected to the wall surface of the lot hole (31), the second air supply passage (32) communicating with the first air supply passage (14) and the second air discharge passage (33) communicating with the first air discharge passage (15);
a lot (40) reciprocated in the state where the outer peripheral surface thereof comes into contact with the inner peripheral surface of the lot hole (31) and having a depressed groove (41) formed on one side of the outer peripheral surface thereof so that a space is formed between the outer and inner peripheral surfaces of the lot hole (31);
a tube body (50) adapted to surround the outer periphery of the lower body (30), while having an internal space at the inside thereof; and
a float (60) moved up in the internal space of the tube body (50) by means of the buoyancy of oil.

2. The overflow blocking apparatus according to claim 1, wherein the reciprocating directions of the piston (20) and the rod (21) in the first cylinder (11) and the second cylinder (12) become upward and downward directions of the storage tank (T), and an air supply port (16) and an air discharge port (17) connected to the first air supply passage (13) and the first air discharge passage (15) are located on the top of the body (10), the inner diameter of the second cylinder (12) being smaller than the inner diameter of the first cylinder (11), and the inlet of the first air supply passage (13) for injecting the air into the first cylinder (11) being formed on the lower end portion of the first cylinder (11).

3. The overflow blocking apparatus according to claim 1, wherein the body (10) further comprises a venting hole (14) formed on one side of a space in which the spring (22) is mounted in the first cylinder (11), in such a manner as to communicate with the outside.

4. The overflow blocking apparatus according to claim 1, wherein the second air supply passage (32) and the second air discharge passage (33) of the lower body (30) communicate with each other by means of the depressed groove (41) of the lot (40).

5. The overflow blocking apparatus according to claim 1, wherein one side end of the lot (40) protrudes toward the internal space of the second cylinder (12), while the other side end thereof is protruding toward the internal space of the tube body (50), and the lot (40) further comprises a flange (42) disposed on the protruding portion thereof toward the second cylinder (12) to prevent the lot (40) from being escaped from the lower body (30).

6. The overflow blocking apparatus according to claim 1, wherein the tube body (50) comprises at least one or more holes (51) formed thereon in such a manner as to connect the internal space thereof with an outside space.

7. The overflow blocking apparatus according to claim 1, wherein the float (60) has a magnet (51) disposed on top thereof, and at least a portion of the lower body (30) is made of a metal material attachable to the magnet (51).

8. An overflow blocking apparatus for a tank lorry, comprising:
overflow sensors (A) disposed on top of a storage tank (T) to sense whether oil overflows; and
a ground sensor (70) electrically short-circuited by the air supplied when the overflow of the oil is sensed by the overflow sensors (A) to block the supply of the oil.

9. The overflow blocking apparatus according to claim 8, wherein the ground sensor (70) comprises:
a cylinder housing (71) having an ascending/descending space formed at the interior thereof and an inlet (72) formed on one side thereof to introduce the air supplied from the overflow sensor (A) into the ascending/descending space;
a first ground member (73) disposed on the lower portion of the cylinder housing (71);
a second ground member (75) disposed ascendably and descendably in the ascending/descending space in such a manner as to be brought into contact with the first ground member (73) when moved down and to be separated from the first ground member (73) when moved up; and
an elastic body (74) for moving the second ground member (75) to the first ground member (73) when the air is not introduced from the inlet (72).
